(19) United States
(12) Patent Application Publication
(10) Pub. No.: US 2009/0075216 A1
(43) Pub. Date: Mar. 19, 2009

(54) STORAGE MEDIUM STORING EXPOSURE CONDITION DETERMINATION PROGRAM, EXPOSURE CONDITION DETERMINATION METHOD, EXPOSURE METHOD, AND DEVICE MANUFACTURING METHOD

(75) Inventor: Tomoaki Kawakami, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/209,040

(22) Filed: Sep. 11, 2008

(30) Foreign Application Priority Data
Sep. 14, 2007 (JP) 2007-239308

(51) Int. Cl. G03F 7/22; G03B 27/54

(52) U.S. Cl. 430/322; 355/67

(57) ABSTRACT

A computer-readable storage medium storing a program for causing a computer to execute determination of an exposure condition for use in illuminating an original plate with an illumination optical system and projecting an image of a pattern of the original plate onto a substrate through a projection optical system. The program causes the computer to perform operations including setting a light intensity distribution on a pupil plane in the illumination optical system based on a constraint condition concerning an optical element constituting the illumination optical system, calculating the image of the pattern of the original plate to be projected onto the substrate using the light intensity distribution, and determining the exposure condition for exposing the substrate with the image of the pattern of the original plate based on a calculation result of the image of the pattern of the original plate and the constraint condition.

### BACKGROUND OF THE INVENTION

1. Field of the Invention

The present invention relates to a storage medium storing a program for determining an exposure condition, a method for determining the exposure condition, an exposure method, and a device manufacturing method.

2. Description of the Related Art

In recent years, a circuit pattern with a narrower line width (i.e., fine patterning) has been used for semiconductor devices. In order to realize this fine patterning, techniques for improving the resolution of a pattern that is projected onto a wafer in an exposure apparatus are being developed.

One of such techniques, which is referred to as a off-axis illumination technique, is used in adjusting an effective light source according to a pattern of a mask (reticle) so as to increase resolution. The effective light source according to this technique represents an angle distribution of exposure light incident on a surface to be illuminated, and also represents a light intensity distribution on a pupil plane of a projection optical system. The effective light source can be implemented by adjusting a light intensity distribution on a pupil plane (i.e., a Fourier transform plane with respect to a mask surface, e.g., a vicinity of the exit surface of a fly-eye lens) of an illumination optical system to a desired shape. Typical shapes of off-axis illumination include annular, dipole, and quadrupole shapes.

These days, in addition to the typical off-axis illumination shapes, there is an increasing need for arbitrary illumination shapes in order to realize a finer circuit pattern. As a method for calculating an optimum effective light source shape for a given reticle, Japanese Patent Application Laid-Open No. 2004-247737 discusses a method by which an effective light source is determined by calculating and evaluating a pattern image projected onto a wafer according to a simulation.

According to the method discussed in Japanese Patent Application Laid-Open No. 2004-247737, an optimum effective light source is searched for and determined according to a result of calculation obtained from an image projected onto the wafer without introducing any restrictions on the effective light source. However, actual exposure apparatuses cannot always form the determined effective light source. In such a case, an effective light source similar to the determined effective light source may be formed and used for exposure processing.

Accordingly, an image actually projected onto the wafer may be different from an image obtained by simulation. Thus, according to the above-described simulation, since an illumination condition of an effective light source that is actually used is not accurate, the calculation of the effective light source may be low in accuracy. In addition, it is required to examine whether the calculated effective light source can be actually formed by an exposure apparatus. As a result, considerable time and cost are required to determine an exposure condition for use in actual exposure processing.

### SUMMARY OF THE INVENTION

The present invention is directed to a storage medium storing a program capable of shortening a time required to determine an exposure condition for use in actual exposure processing, and a method capable of shortening a time required to determine an exposure condition for use in actual exposure processing.

According to an aspect of the present invention, there is provided a computer-readable storage medium storing a program for causing a computer to execute determination of an exposure condition for use in illuminating an original plate with an illumination optical system and projecting an image of a pattern of the original plate onto a substrate through a projection optical system. The program causes the computer to perform operations including setting a light intensity distribution on a pupil plane in the illumination optical system based on a constraint condition concerning an optical element constituting the illumination optical system, calculating the image of the pattern of the original plate to be projected onto the substrate using the light intensity distribution, and determining the exposure condition for exposing the substrate with the image of the pattern of the original plate based on a calculation result of the image of the pattern of the original plate and the constraint condition.

According to another aspect of the present invention, there is provided a computer-readable storage medium storing a program for causing a computer to execute determination of an exposure condition for use in illuminating an original plate with an illumination optical system and projecting an image of a pattern of the original plate onto a substrate through a projection optical system. The program causes the computer to perform operations including setting a light intensity distribution by selecting data from a data group of light intensity distributions formable by the illumination optical system on a pupil plane in the illumination optical system, calculating the image of the pattern of the original plate to be projected onto the substrate using the light intensity distribution, and determining the exposure condition for exposing the substrate with the image of the pattern of the original plate based on a calculation result of the image of the pattern of the original plate and the data group.

According to yet another aspect of the present invention, there is provided a method for determining, using a computer, an exposure condition for use in illuminating an original plate with an illumination optical system and projecting an image of a pattern of the original plate onto a substrate through a projection optical system. The method includes setting a light intensity distribution on a pupil plane in the illumination optical system based on a constraint condition concerning an optical element constituting the illumination optical system, calculating the image of the pattern of the original plate to be projected onto the substrate using the light intensity distribution, and determining the exposure condition for exposing the substrate with the image of the pattern of the original plate based on a calculation result of the image of the pattern of the original plate and the constraint condition.

According to yet another aspect of the present invention, there is provided a method for determining, using a computer, an exposure condition for use in illuminating an original plate with an illumination optical system and projecting an image of a pattern of the original plate onto a substrate through a projection optical system. The method includes setting a light intensity distribution by selecting data from a data group of light intensity distributions formable by the illumination optical system on a pupil plane in the illumination optical system, calculating the image of the pattern of the original plate to be projected onto the substrate using the light intensity distribution, and determining the exposure condition for exposing the substrate with an image of the pattern of the original plate based on a calculation result of the image of the pattern of the original plate and the data group.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIG. 1 illustrates an example configuration of an exposure apparatus according to an exemplary embodiment of the present invention.

FIG. 2 illustrates an example configuration of a computer according to an exemplary embodiment of the present invention.

FIG. 3 is a flowchart illustrating calculation of an exposure condition according to a first exemplary embodiment of the present invention.

FIG. 4 is a flowchart illustrating calculation of an exposure condition according to a second exemplary embodiment of the present invention.

FIG. 5A is a schematic diagram of an annular illumination.

FIG. 5B illustrates a conical prism.

FIG. 6A is a schematic diagram of a quadrupole illumination.

FIG. 6B illustrates a pyramidal prism.

FIG. 7A illustrates a combination of conical prisms when the spacing between the conical prisms is small.

FIG. 7B is a schematic diagram of an annular illumination with a wide light emitting area.

FIG. 8A illustrates a combination of conical prisms when the spacing between the conical prisms is large.

FIG. 8B is a schematic diagram of an annular illumination with a narrow light emitting area.

FIG. 9A is a plan view of an effective light source with a top-hat shape.

FIG. 9B is a cross section of light intensity of the effective light source illustrated in FIG. 9A.

FIG. 10A is a plan view of an effective light source.

FIG. 10B is a cross section of light intensity of the effective light source illustrated in FIG. 10A.

FIGS. 11A and 11B are cross sections of light intensity of effective light sources.

FIGS. 11C and 11D are plan views of the effective light sources illustrated in FIGS. 11A and 11B, respectively.

FIGS. 12A and 12B illustrate effective light sources.

FIGS. 13A through 13F illustrate shapes of effective light sources and polarization states.

FIGS. 14A and 14B illustrate an exposure apparatus in a state where an effective light source is measured.

FIGS. 15A through 15C illustrate shapes of light blocking members.

### DETAILED DESCRIPTION OF THE EMBODIMENTS

Various exemplary embodiments, features, and aspects of the invention will be described in detail below with reference to the drawings.

### First Exemplary Embodiment

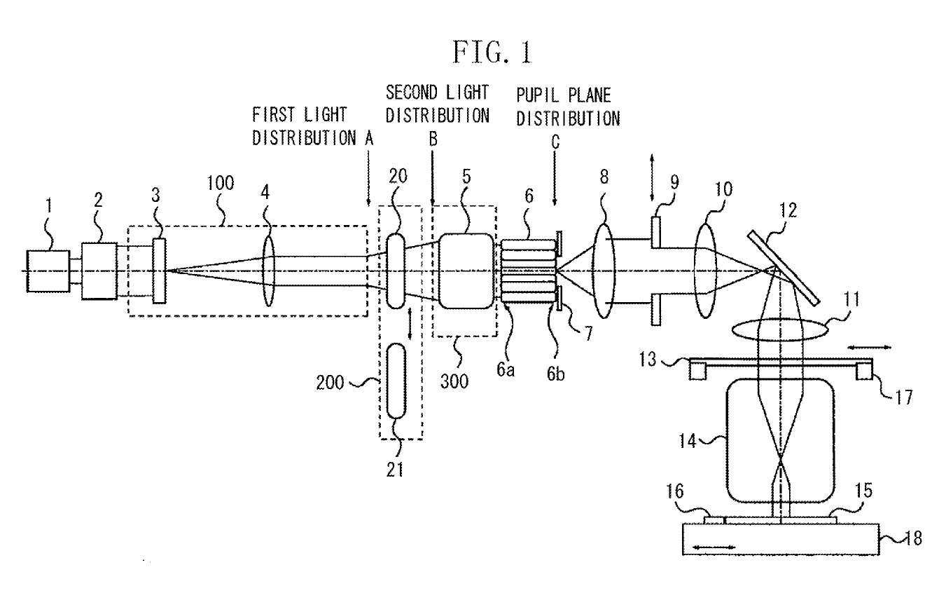

FIG. 1 illustrates an example configuration of an exposure apparatus according to a first exemplary embodiment of the present invention. According to the present exemplary embodiment, an optical system located between a light source 1 and a mask 13 is referred to an illumination optical system.

The light source 1 is, for example, an excimer laser or an ultrahigh pressure mercury lamp that emits a light beam in an ultraviolet region or a far ultraviolet region. Light emitted from the light source 1 is shaped into a light flux of a desired shape by a light flux shaping optical system 2, and is then incident on a diffractive optical element 3. The diffractive optical element 3 is designed such that when a collimated light beam is incident on the diffractive optical element 3, a predetermined light intensity distribution is formed on a Fourier transform plane with respect to the diffractive optical element 3. A light beam that exits the diffractive optical element 3 passes through a Fourier transform lens 4, which forms a first light distribution on a first light distribution plane. The diffractive optical element 3 is switchable depending on the type of effective light source desired to be formed.

Each of illumination shape conversion units 20 and 21 includes an element for converting the light flux that has passed through the first light distribution plane into shapes such as annular or quadrupole shape according to the shape of an effective light source (e.g., circular illumination, annular illumination, or quadrupole illumination).

A collective zoom optical system 5 forms an image on an entrance surface 6a of a fly-eye lens 6 with the light flux from a second light distribution plane at a predetermined magnification. The second light distribution plane of the collective zoom optical system 5 and the entrance surface 6a of the fly-eye lens 6 form a substantially conjugated relationship. The collective zoom optical system 5 has a variable magnifying power and is thus able to adjust an area of a light beam incident on the fly-eye lens 6, thereby changing illumination conditions of the effective light source.

The fly-eye lens 6 includes a plurality of microlenses that are arranged two-dimensionally. An exit surface 6b of the fly-eye lens 6 serves as a pupil plane of the illumination optical system, so that a pupil plane distribution (i.e., a light intensity distribution on the pupil plane of the illumination optical system) is formed accordingly. It is to be noted that, a combination of a great number of rod lenses (or, microlens elements) or a plurality of sets of cylindrical lens array plates each of which is arranged orthogonal to one another can be used as the fly-eye lens 6. A diaphragm member 7 configured to block unnecessary light to achieve a desired light distribution is located on the pupil plane of the illumination optical system. The dimension and shape of the aperture of the diaphragm member 7 can be changed by a diaphragm driving mechanism (not shown).

An illumination lens 8 is configured to superpose light beams exiting a plurality of lens elements of the fly-eye lens 6 onto a field stop 9.

The field stop 9 includes a plurality of movable light-blocking plates for arranging the aperture into a desired shape. Thus, the field stop 9 regulates an exposure range on the surface of a mask (reticle) 13 (or a wafer 15), which is a surface to be illuminated. Imaging lenses 10 and 11 are configured to transfer the aperture shape of the field stop 9 onto the mask 13. A deflecting mirror 12 is located between the imaging lenses 10 and 11.

The mask 13, which serves as an original plate, is supported by a mask stage 17 and is controlled by a driving apparatus (not shown). A projection optical system 14 is configured to project a circuit pattern of the mask 13 onto the surface of the wafer 15 in a reduced size.

The wafer 15, which serves as a substrate, is located on an exposure plane, which is an image-forming plane of the projection optical system 14. The circuit pattern formed on the mask 13 is transferred onto the surface of the wafer 15 by projection. A wafer stage 18, which supports the wafer 15, is movable in an optical axis direction and a direction perpendicular to the optical axis. The movement of the wafer stage 18 is controlled by a driving apparatus (not shown). When the exposure process is performed, the mask stage 17 and the wafer stage 18 are driven for exposure scanning in synchronization with each other in directions indicated by arrows in FIG. 1.

A detector 16 is provided for detecting the quantity of exposure light incident on the surface of the wafer 15. The detector 16 has a light receiving unit, which is aligned with the surface of the wafer 15. The detector 16 moves according to a driving operation of the wafer stage 18 and receives exposure light within an exposure region. Then, the detector 16 sends a signal corresponding to an output thereof to a main controller (not shown). The main controller is configured to control driving mechanisms and also stores information on the pupil plane distribution and information on the total quantity of light transmitted through the pattern of the mask 13.

According to the present exemplary embodiment, the diffractive optical element 3 and the Fourier transform lens 4 are referred to as a first optical unit 100, the illumination shape conversion units 20 and 21 are referred to as a second optical unit 200, and the collective zoom optical system 5 is referred to as a third optical unit 300. Further, a light intensity distribution formed by the first optical unit 100 is referred to as a first light distribution (A), a light intensity distribution formed by the second optical unit 200 is referred to as a second light distribution (B), a light intensity distribution formed by the third optical unit 300 is referred to as a pupil plane distribution (C). The pupil plane distribution (C) is synonymous with an effective light source. It is also synonymous with an angle distribution of light incident on the surface to be illuminated.

The first through third optical units 100, 200, and 300 convert a light beam emitted from the light source 1 into a desired shape and control the light intensity distribution and angle distribution of a light beam on the entrance surface of the fly-eye lens 6 to adjust the light intensity distribution on the pupil plane of the illumination optical system.

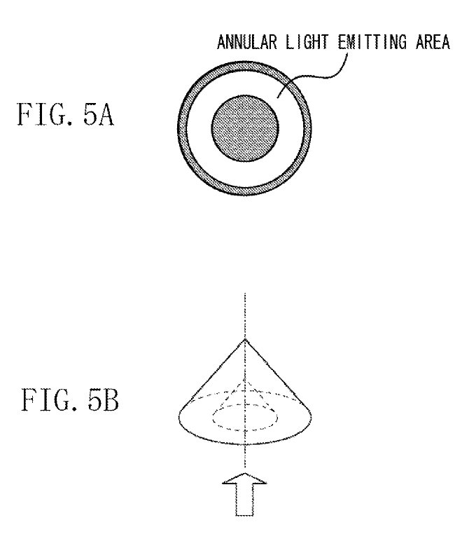

The second optical unit 200 is described now in detail. In forming an effective light source having an annular shape as illustrated in FIG. 5A, an illumination shape conversion unit having, for example, an optical prism with a concave conical surface on its entrance side and a convex conical surface on its exit side as illustrated in FIG. 5B can be used. The entrance side can also be a flat surface.

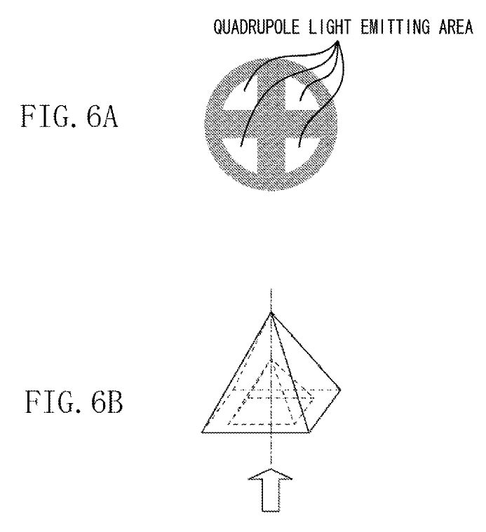

On the other hand, in forming a quadrupole effective light source as illustrated in FIG. 6A, an illumination shape conversion unit having, for example, an optical prism with a concave quadrangular-pyramid surface on its entrance side and a convex quadrangular-pyramid surface on its exit side as illustrated in FIG. 6B can be used. The entrance side can also be a flat surface. An angle formed between each ridge line of the quadrangular pyramid on the entrance side and the optical axis and an angle formed between each ridge line of the quadrangular pyramid on the exit side and the optical axis are arranged to be equal but may also be arranged to be different so as to improve illumination efficiency. The same arrangement can be applied to the conical prism described above. Further, the quadrupole illumination can also be formed by forming a quadrupole light distribution on the first light distribution by the diffractive optical element 3 and arranging an optical prism having a concave conical surface or a flat surface on its entrance side and a convex conical surface on its exit side.

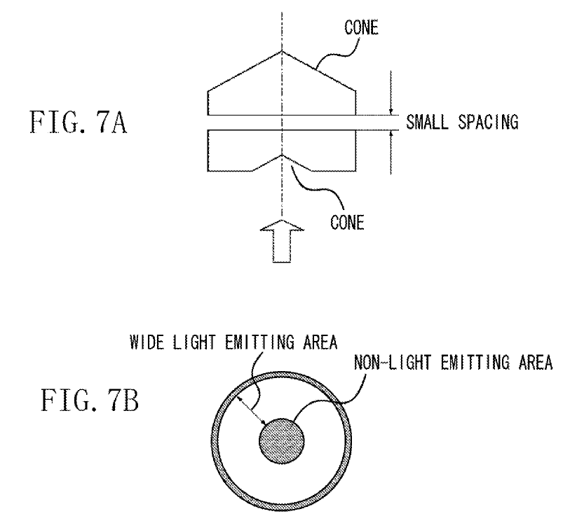

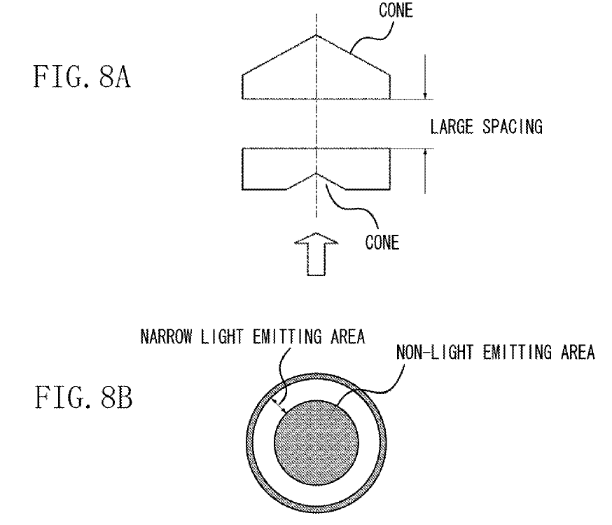

Furthermore, effective light sources of various shapes can be formed when an illumination shape conversion unit includes a pair of prisms as illustrated in FIGS. 7A and 8A, which are relatively movable in the optical axis direction. The pair of prisms illustrated in FIGS. 7A and 8A includes a first prism and a second prism. The first prism has a concave conical surface on its entrance side and a flat surface on its exit side. The second prism has a flat surface on its entrance side and a convex conical surface on its exit side. When the spacing between the first and the second prisms is small as illustrated in FIG. 7A, an annular effective light source with a wide light emitting area and a low annular ratio is formed as illustrated in FIG. 7B. When the spacing between the first and the second prisms is large as illustrated in FIG. 8B, an annular effective light source with a narrow light emitting area and a high annular ratio is formed as illustrated in FIG. 8B. Further, by combining the pair of prisms with the collective zoom optical system 5 in the subsequent stage, the size (i.e., σ value) of the effective light source can be adjusted while maintaining the annular ratio.

For example, in forming the annular effective light source illustrated in FIG. 5A, the first light intensity distribution (A) formed by the first optical unit 100 is given a circular shape, and the second light intensity distribution (B) formed by the second optical unit 200 is given an annular shape. By driving the optical element (prism) of the second optical unit 200, the annular ratio, which is the ratio of the inner diameter to the outer diameter of the annular shape, can be adjusted. Further, by combining the first and the second optical units 100 and 200 with the third optical unit 300, the size of the effective light source can be adjusted while maintaining the shape of the second light intensity distribution (B).

Next, an exposure condition for use in exposure processing according to the present exemplary embodiment will be described. According to the present exemplary embodiment, the above-described optical system is used in the exposure processing.

The present exemplary embodiment can be mathematically modeled and implemented using software that runs on a computer system. The software function of the computer system according to the present exemplary embodiment includes a program including executable code. Data on illumination conditions can be obtained using the program. The software code can be stored in at least one machine-readable medium as one or a plurality of modules. The present invention described below is described in the form of the above-described code and can be implemented as one or a plurality of software products.

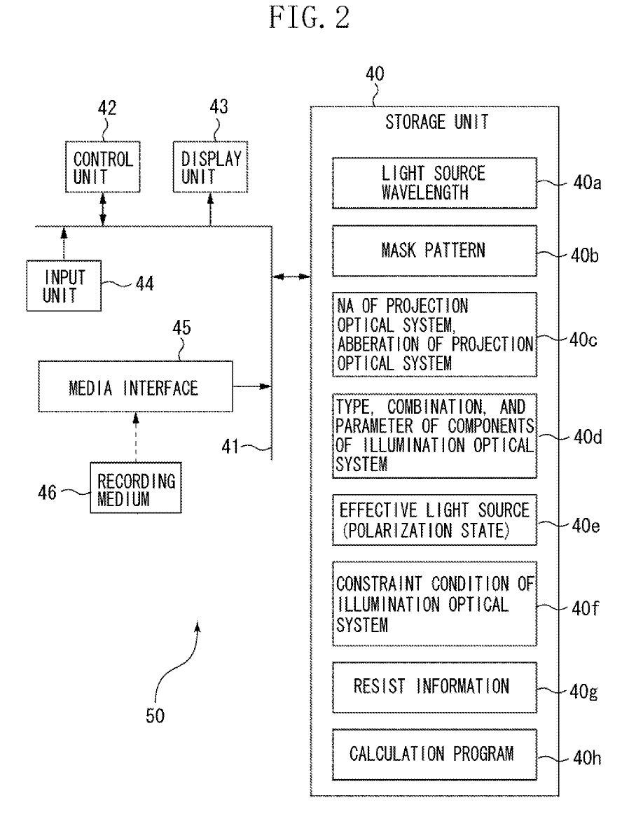

FIG. 2 illustrates an example configuration of a computer for executing an exposure condition calculation program according to the present exemplary embodiment. A computer 50 includes a bus 41, a control unit 42, a display unit 43, a storage unit 40, an input unit 44, and a media interface 45. The control unit 42, the display unit 43, the storage unit 40, the input unit 44, and the media interface 45 are connected to one another via the bus 41. The media interface 45 is configured to be connectable to a recording medium 46.

Various types of data including data 40a on a light source wavelength, data 40b on a mask pattern, and data 40c on a numerical aperture (NA) and aberration on the exit side of the projection optical system are stored in the storage unit 40. Further, data 40d on the type, combination, and parameter of optical elements constituting the illumination optical system, data 40e on an effective light source including a polarization state, data 40f on a constraint condition of the illumination optical system, resist information 40g, and an exposure condition calculation program 40h are also stored in the storage unit 40. According to the present exemplary embodiment, the data on an effective light source is data on a light intensity distribution formed on the pupil plane of the projection optical system or the illumination optical system of the exposure apparatus. The exposure condition includes parameters concerning exposure of a substrate (i.e., exposure parameters), such as a spectral distribution (wavelength distribution) of a wavelength of a light source, components of the illumination optical system (which is described below), parameters of the components, an effective light source, and aberration of the projection optical system.

The control unit 42 includes, for example, a central processing unit (CPU), a graphics processing unit (GPU), or a digital signal processor (DSP). The control unit 42 calculates and determines an exposure condition using the storage unit 40. The control unit 42 further includes a cache memory for temporary storage. The display unit 43 is a display device such as a cathode ray tube (CRT) display or a liquid crystal display. The storage unit 40 is a storage device such as a memory or a hard disk. The input unit 44 is an input device such as a keyboard or a mouse. The media interface 45 is, for example, a floppy disk drive, a compact disc read-only memory (CD-ROM) drive, or a universal serial bus (USB) interface. The storage medium 46 is, for example, a floppy disk, a CD-ROM, or a USB memory.

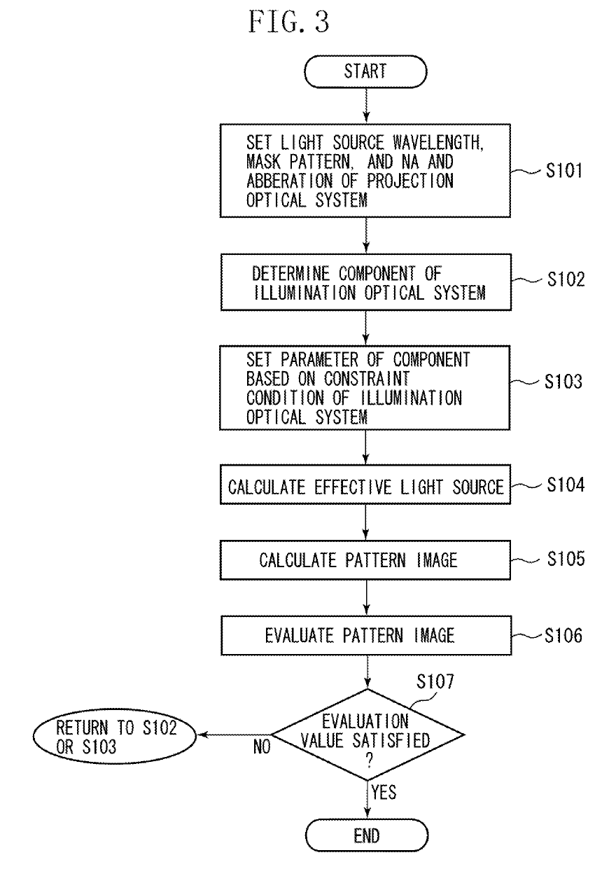

Next, a flow of calculating the exposure condition will be described with reference to FIG. 3.

In step S101, the control unit 42 sets a light source wavelength (e.g., center wavelength, half width), a mask pattern, NA on the exit side of the projection optical system, and aberration of the projection optical system, and stores them in the storage unit 40. As the mask pattern, the entire circuit pattern of the device can be set. However, a representative portion of the pattern can also be set. The representative pattern includes groups of same patterns that are frequently seen on the mask and groups of critical patterns having a low image-forming margin. The same patterns are those typified by a memory cell of a dynamic random access memory (DRAM) having the same vertical and horizontal patterns. On the other hand, the critical patterns are those that do not have similar patterns nearby, isolated patterns, patterns that are assumed to have low image-forming margin, or patterns of an area that is electrically sensitive.

In step S102, the control unit 42 determines an optical element (component) that constitutes the illumination optical system and stores the result in the storage unit 40. The effective light source is dependent on a combination of the optical units concerned with the formation of the effective light source and a state of the zoom optical system. According to the present exemplary embodiment, a unit that is directly related to the formation of the effective light source is called an effective light source forming unit. The effective light source forming unit is a switchable optical unit of the illumination optical system that includes components from the diffractive optical element 3 to the diaphragm member 7 illustrated in FIG. 1.

The switchable optical unit includes the first optical unit 100 configured to determine a reference distribution of the effective light source (i.e., first light distribution), the second optical unit 200 configured to deform the first light distribution, a polarizing element (not shown) configured to determine a polarization state of the effective light source, a light blocking member (such as a diaphragm), and a light attenuation member.

For example, in step S102, the control unit 42 selects and determines an optical element that is to be used from among a plurality of illumination shape conversion units (e.g., optical elements illustrated in FIGS. 5A through 8B). Additionally, the control unit 42 determines which diffractive optical element will be used and further determines whether a polarizing element, a light blocking member or a light attenuation member will be used. The polarizing element can be disposed at any location so long as it forms a polarization state on the pupil plane. For example, the polarizing element can be arranged in the vicinity of the entrance surface of the fly-eye lens 6. The location of the light blocking member is also not limited and can be provided at any location between the diffractive optical element 3 and the diaphragm member 7. For example, the light blocking member can be arranged at a position where the diaphragm member 7 is set or on the first light distribution plane.

In step S103, the control unit 42 sets an initial value of a parameter of the component of the illumination optical system based on a constraint condition of the illumination optical system and stores the initial value in the storage unit 40. The constraint condition of the illumination optical system is a condition under which the illumination optical system is designed. For example, the condition is a range in which the component of the illumination optical system can be designed, manufactured, and used. More specifically, the condition includes a movable range of the lens constituting the collective zoom optical system 5 in the optical axis direction, a range of an angle which the ridge line of a prism constituting the illumination shape conversion unit forms with the optical axis, or a shape of the light blocking member (e.g., angular range of the aperture). Lower limits and upper limits of these ranges express manufacture limits and application limits.

Further, an upper limit of energy density of light incident on an optical element of the illumination optical system and a lower limit of illuminance (amount of exposure) on the wafer (substrate) can also be used as a constraint condition concerning a light attenuation member or light blocking member. Furthermore, since the illuminance on the substrate also changes according to the diffraction efficiency of the diffractive optical element constituting the illumination optical system and the transmittance of a zoom lens or prism, the diffraction efficiency or transmittance of the optical element can be considered in selecting the component of the illumination optical system or setting the parameter.

The constraint condition of the illumination optical system can be set using data stored in advance in the storage unit 40.

The parameter of the component of the illumination optical system is, for example, the position of a lens constituting the collective zoom optical system 5 in the optical axis direction, an angle formed by the ridge line of a prism constituting the illumination shape conversion unit with the optical axis, a shape (angle) of the light blocking member, or the transmittance of the light attenuation member.

In step S104, the control unit 42 reads the light source wavelength set in step S101, the components of the illumination optical system determined in step S102, and the parameters of the components set in step S103 from the storage unit 40 to acquire an effective light source. The effective light source can be acquired by ray tracing using the optical parameter of the optical element. Further, for example, alight intensity a at a point on the pupil plane having coordinates (xE, yE) can be expressed by the following equation (1). The light intensity a is determined by parameters (a, b, c, . . . ) including a combination of optical elements.

α(xE, yE)=f(xE, yE, a, b, c, . . . ) (1)

effective light source distribution=ΣΣα(xE, yE) (2)

In equation (1), the light intensity α(xE, yE) at a point on the pupil plane having coordinates (xE, yE) can be expressed by a function of coordinates (xE, yE) and parameters a, b, c . . . . If the entire pupil plane is calculated according to equation (1) and summed using equation (2), an effective light source that corresponds to the parameter including the combination of optical elements can be obtained.

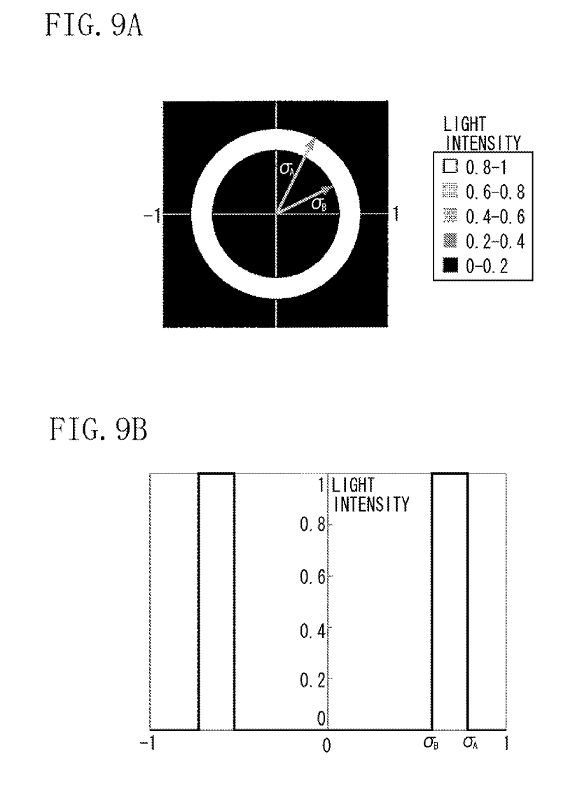

The effective light source can be expressed using the σ value. The σ value is obtained by dividing the NA on the exit side of the illumination optical system by the NA on the entrance side of the projection optical system. For example, regarding the annular illumination illustrated in FIG. 9A, σA is referred to as outer σ, and σB is referred to as inner σ.

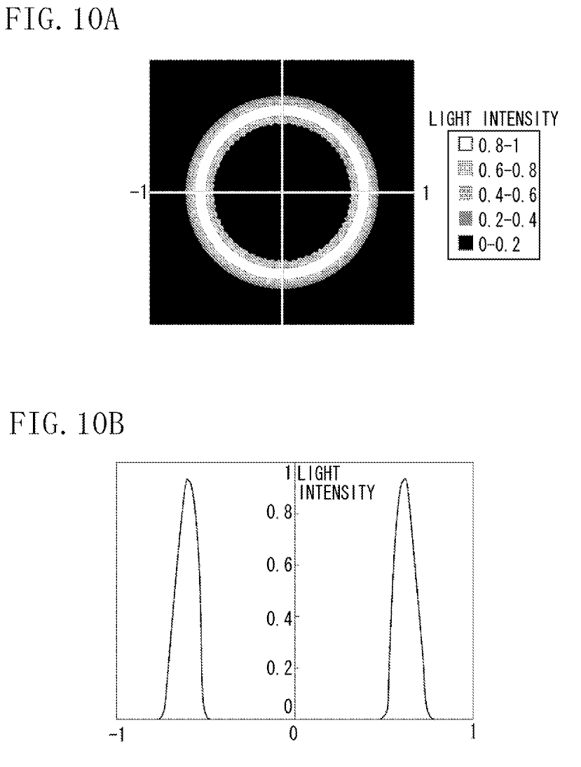

FIG. 9B is a cross section of light intensity of the effective light source illustrated in FIG. 9A. A maximum value of the light intensity is normalized as 1. In FIG. 9B, the cross section of the light intensity has a top-hat shape. With respect to the actual illumination optical system, inmost cases, the light intensity distribution is not in a top-hat shape in a certain cross section (see FIGS. 10A and 10B). This occurs, for example, since a light beam incident on the first light distribution has a certain angle distribution. Thus, when the light intensity is integrated from the center of the optical axis, a position where the total integrated quantity becomes 10% can be referred to as outer σ and a position where the total integrated quantity becomes 90% can be referred to as inner σ. The outer σ is greater than the inner σ.

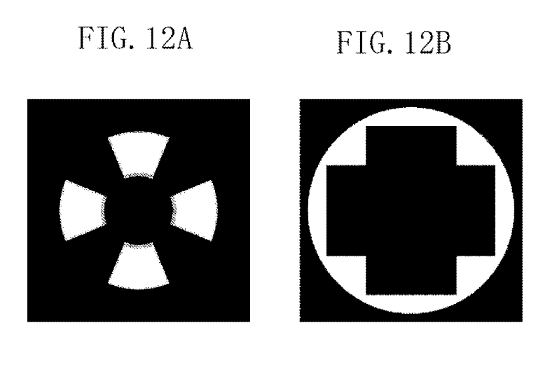

If the effective light source is annular or multipolar as illustrated in FIGS. 12A and 12B and the shape is rotationally symmetrical or line symmetrical, a portion of the effective light source (e.g., one pole or position) rather than the entire area can be calculated to simplify calculation. The calculated portion can be used in calculating the entire effective light source.

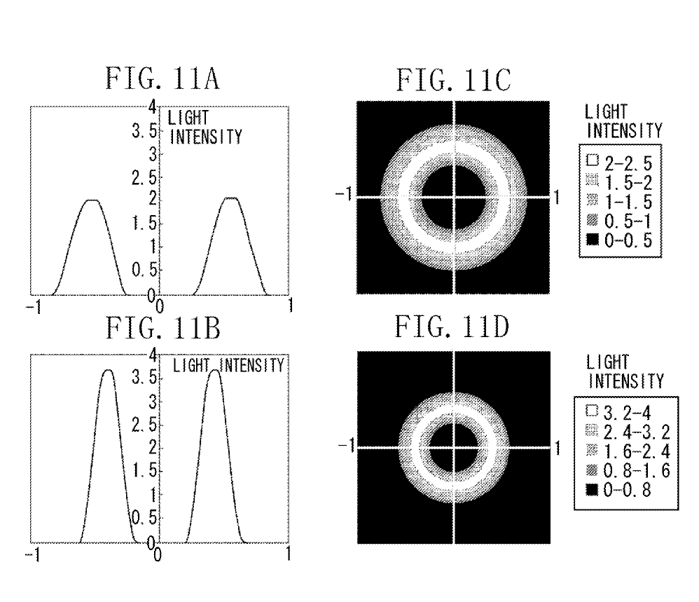

Next, an exemplary method for calculating the effective light source will be described. The effective light source can be calculated from a transition of sectional light intensity. FIG. 11A illustrates an example of sectional light intensity of an effective light source. Since the sectional light intensity changes according to a zoom parameter of the collective zoom optical system, if this transition is defined as a function of the zoom parameter, the effective light source can be calculated for each parameter. For example, by changing zoom of the optical system that changes the size of the effective light source, the sectional light intensity will be changed from the sectional light intensity illustrated in FIG. 11A to the one illustrated in FIG. 11B. The effective light source, at this time, changes from the effective light source illustrated in FIG. 11C to the one illustrated in FIG. 11D. By expressing transition of the light intensity in the cross section by a mathematical expression, a light intensity using an arbitrary parameter of the zoom optical system, which is, in other words, an effective light source, can be obtained. According to this method, an effective light source that is appropriate for the exposure apparatus can be calculated.

In step S105, the control unit 42 reads the data set or obtained in steps S101 and S104 from the storage unit 40 and calculates an image of the pattern of the mask to be projected onto the wafer. This image of the pattern of the mask (i.e., intensity distribution) can be calculated based on optical calculation, such as Abbe's theory of imaging.

In step S106, the control unit 42 evaluates the calculated image of the pattern (the calculation result). Evaluation indices includes, for example, image size (image width, critical dimension), depth of focus (DOF) of image, sensitivity of image to light intensity, exposure latitude, exposure latitude sensitivity, contrast, and mask error factor (MEF). Further, side-lobe of image and light intensity distribution gradient (i.e., value obtained by differentiating image intensity with respect to position) are also included in the evaluation indices. According to the present exemplary embodiment, a difference of two results obtained by changing parameters and repeatedly calculating the light intensity distribution is referred to as the sensitivity.

In step S107, the control unit 42 determines whether an evaluation value, which is a value obtained with reference to the indices, satisfies a reference value or is in a range of reference values which are determined in advance. If the evaluation value is determined to satisfy the reference value (YES in step S107), then the control unit 42 outputs the component data determined in step S102, the parameter data set in step S103, and the effective light source data calculated in step S104. The output data on the effective light source is determined, together with other exposure conditions (e.g., wavelength distribution of light source and aberration of the projection optical system) set in step S101, as an exposure condition that will be actually used in the exposure processing. The determined exposure conditions are stored in the storage unit 40, and then the process ends.

If the control unit 42 determines that the evaluation value does not satisfy the reference value (NO in step S107), then the process returns to step S102 or S103. If the process returns to step S102, the component of the illumination optical system is changed and then steps S103 through S107 are be performed. If the process returns to step S103, the parameter of the component is changed while the component is unchanged. Then, steps S104 through S107 are performed. In this way, step S102 or S103 through step S107 are repeated until the evaluation value is determined to satisfy the reference value in step S107.

In step S107, the control unit 42 determines that the evaluation value satisfies the reference value and further determines the evaluation value as an exposure condition to be used for the actual exposure processing. Then, the component in the illumination optical system is designed, manufactured, or selected based on the component data and the component parameter data from among the exposure conditions stored in the storage unit 40. Then, exposure and development processing is performed using the illumination optical system that includes the component and the light source and the projection optical system which are controlled by the control apparatus to satisfy the exposure condition.

If it is determined that the evaluation result obtained in step S106 is extremely poor, the process can return to step S102 and not to S103. If the evaluation result obtained in step S106 is near optimal and only a slight adjustment of the parameter is required, the process can return to step S103. Instep S103, the parameter can be adjusted in detail. Further, by using the conventional optimization method, the process can return to step S102 or S103 as appropriate, and step S102 or S103 through step S107 can be repeated to achieve optimum image performance.

On the other hand, calculation, evaluation, and confirmation of the pattern image with respect to all values in the setting range of the parameters (within the constraint condition) of a certain component can be performed before the process returns to step S102. In step S102, the pattern image is calculated and evaluated with respect to all values in a parameter setting range of a different component (within the constraint condition). In this case, a plurality of solutions (e.g., components or parameters), which are determined to satisfy the reference value in step S107, are compared and the best solution is selected. By using the selected solution, the exposure/development processing can be performed. For example, the exposure condition is determined such that any one of the depth of focus, exposure latitude, and angle of light intensity distribution (value obtained by differentiating image intensity with respect to position) takes its maximum value.

If the control unit 42 determines that the evaluation value does not satisfy the reference value in step S107, then the mask pattern which is set in step S101 or the aberration of the projection optical system which is also set in step S101 can be changed. In changing the mask pattern, optical proximity correction (OPC) can be considered or an auxiliary pattern can be arranged to enhance the resolution of the mask pattern. Further, an exposure condition other than the light intensity distribution on the pupil plane of the projection optical system or the illumination optical system, such as a mask pattern, NA on the exit side of the projection optical system, and aberration, can be set at any timing so long as it is performed before step S105.

Furthermore, a resist image, which is to be formed on the resist applied to the wafer, can be calculated by calculating the pattern image to be projected onto the wafer and using the resist information 40g. Then, evaluation of the resist image can be performed in place of step S106. Then, the process proceeds to step S107 to obtain the optimal exposure condition.

According to the present exemplary embodiment, only the exposure condition which can be actually used by the exposure apparatus can be calculated. According to a conventional method, an exposure condition using an optical element that is unmanufacturable or difficult to manufacture and thus not included in the exposure apparatus may be obtained as a solution of the exposure condition of the exposure apparatus. According to the present exemplary embodiment, since an actual exposure result can be reproduced with accuracy, an image or resist image to be projected onto the substrate can be calculated more accurately.

For example, according to the present exemplary embodiment, a solution of an exposure condition concerning an optical element that is not included in the exposure apparatus but can be manufactured can be obtained. Based on the data on the optical element that is manufacturable, such an optical element can be designed and manufactured without difficulty. Further, since various exposure conditions are determined, when the manufacture or selection of the optical element is completed, the exposure apparatus can be operated at once. Thus, a development period, which is a period from the start of the calculation of the exposure condition to the time when the process reaches the volume-production stage of devices (i.e., a time required to determine an exposure condition actually used in the exposure processing), can be shortened.

### Second Exemplary Embodiment

A second exemplary embodiment of the present invention will now be described. The present exemplary embodiment differs from the first exemplary embodiment in that information on the effective light source is stored in the database. Descriptions of components that are the same as or alternatively similar to ones in the above-described first exemplary embodiment are omitted for simplification.

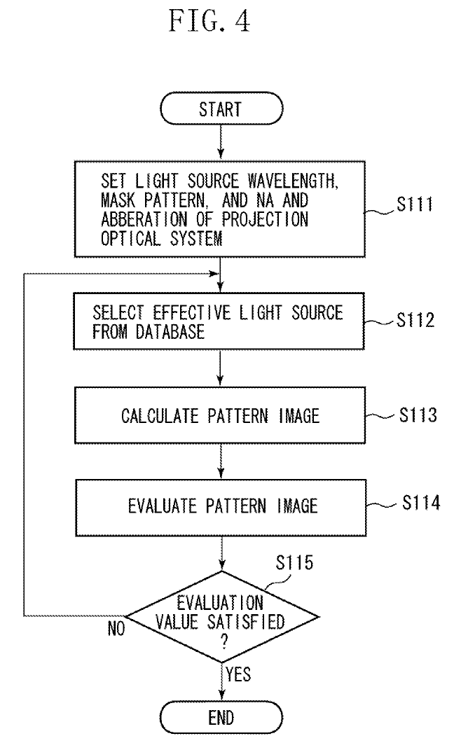

FIG. 4 is a flowchart illustrating calculation of an exposure condition according to the present exemplary embodiment. In step S111, the control unit 42 sets a light source wavelength, a mask pattern, NA on the exit side of the projection optical system, and aberration of the projection optical system, and stores these data in the storage unit 40. In step S112, the control unit 42 selects an effective light source as an initial value from the database (data group) stored in the storage unit.

Data on the effective light source corresponding to a value of a parameter of the component is input in advance in the database for each optical element constituting the illumination optical system or each combination of such elements. Data volume of the effective light source is determined considering a storage capacity of the storage unit and calculation accuracy that is required. Further, in obtaining data of the entire effective light source, data of a portion of the effective light source can first be obtained by using parameters of a given portion. For example, if data on the effective light source is obtained with a lens constituting the collective zoom optical system 5 as a parameter, the lens is moved in the optical axis direction at a regular interval. Data is obtained each time the lens is moved. Then, the data is stored in the database. If the effective light source is rotationally symmetric or line symmetric, the size and position of apart of the effective light source (e.g., pole) can be calculated using mathematical expression or converted into bit-mapped data. Then, the data can be applied to the entire effective light source (e.g., multipole). This contributes to simplifying the calculation processing as well as reducing the capacity of the database.

Similar to the first exemplary embodiment, the control unit 42 calculates the pattern image in step S113, evaluates the pattern image in step S114, and determines whether the evaluation value of the pattern image satisfies the reference value in step S115. If the evaluation value of the pattern image does not satisfy the reference value (NO in step S115), then the process returns to step S112. In step S112, the control unit 42 selects a different effective light source from the database and recalculates the pattern image.

Since the present exemplary embodiment eliminates the necessity for optical calculation, such as ray tracing, using a type or a combination, or parameter of the component of the illumination optical system in the processing from step S111 to step S115, a time required to calculate the exposure condition can further be shortened.

### Third Exemplary Embodiment

A third exemplary embodiment of the present invention will now be described. According to the present exemplary embodiment, in addition to the light intensity distribution on the pupil plane of the illumination optical system, a polarization state of the light is considered. Descriptions of components that are the same as or alternatively similar to ones in the above-described first exemplary embodiment are omitted for simplification.

In addition to light intensity (illuminance), the effective light source is associated with a physical value, such as polarization. Polarization is classified into two types according to the direction of an electric field of the wave with respect to a plane formed by light that passes through a lens and refractively incident on the resist and reflected by the resist. Light with an electric field parallel to this plane is referred to as transverse-magnetic (TM) wave, X polarized wave, or radial polarized wave. Light with an electric field perpendicular to the plane is referred to as transverse-electric (TE) polarized wave, Y polarized wave, or tangential polarized wave. The light with an electric field perpendicular to the plane is used to search for an effective light source, as it can form an optical image with higher contrast.

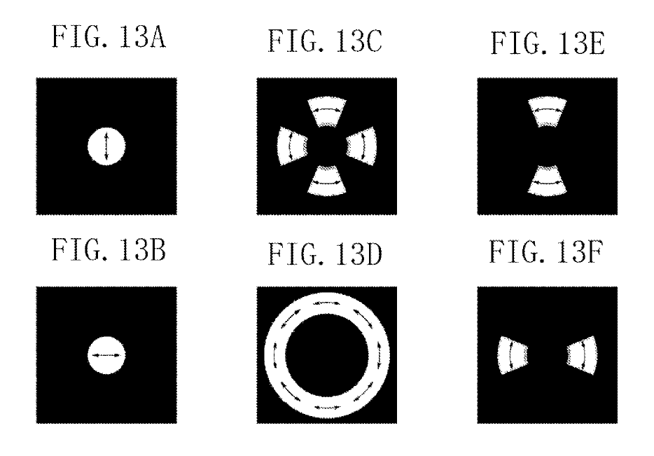

According to the present exemplary embodiment, the above-described polarization state, which is formed in the effective light source forming unit, is incorporated into an illumination shape formed by a combination of optical elements in the effective light source forming unit. More specifically, if the illumination is a circular illumination with a central aperture, then a polarization state illustrated in FIG. 13A or 13B can be used. If the illumination is annular, then a polarization state illustrated in FIG. 13D can be used. If the illumination is multipole illumination, then a polarization state illustrated in FIG. 13C, 13E, or 13F can be used. After the polarization state is incorporated, calculation of the image performance is performed. Arrows illustrated in FIGS. 13A through 13F indicate the polarization direction of light.

Thus, the polarization state is considered in the calculation of the above-described effective light source. Polarized illumination with a polarization state such as those illustrated in FIGS. 13A through 13F is used in the calculation of an image to be projected onto a wafer.

According to the present exemplary embodiment, an exposure condition for an effective light source can be calculated considering polarized illumination, which contributes to improving the resolution of a pattern image.

### Fourth Exemplary Embodiment

A fourth exemplary embodiment of the present invention will now be described. According to the above-described exemplary embodiments, the effective light source is calculated based on a simulation. According to the present exemplary embodiment, an effective light source that is actually formed by the exposure apparatus is measured, and the measured data is used in the determination of an exposure condition. Descriptions of components that are the same as or alternatively similar to ones in the above-described first exemplary embodiment are omitted for simplification.

There are several techniques for measuring the effective light source. For example, in one technique, the field stop 9 is driven to set a micro aperture at a position corresponding to a point on an image plane subject to measurement. Then, the detector 16, which is set in the vicinity of the wafer, is defocused in the direction of the optical axis from a reference plane (image plane) of the wafer. In this case, the mask 13 is removed from the optical path.

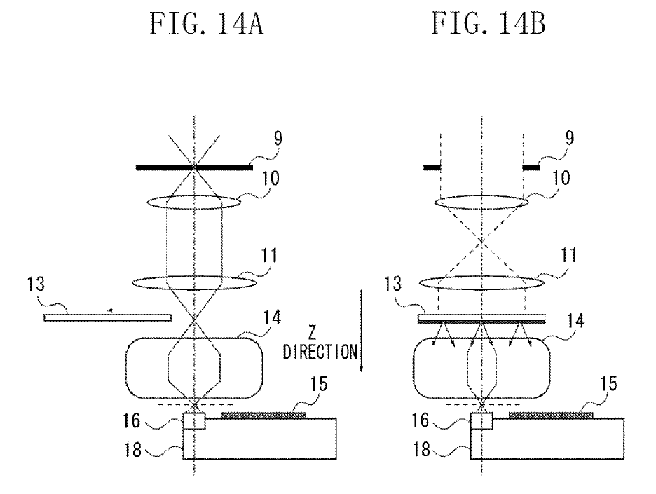

FIG. 14A illustrates the state of the exposure apparatus when this technique is performed. Components illustrated in FIG. 14A, which are similar to those illustrated in FIG. 1, are given the same reference numerals. To simplify the illustration, the deflecting mirror 12 is not illustrated in FIG. 14A.

An image is formed temporarily on the wafer surface only with the exposure light that has passed through the field stop 9. While the angle of the light is maintained, the light enters the detector 16. The detector 16 is disposed on the XY stage 18 configured to support the wafer. A light receiving unit of the detector 16 includes a pinhole having a diameter small enough for the spread of the light beam. The detector 16 is moved horizontally within, for example, a two-dimensional matrix range on the XY stage 18 to measure the intensity of the incident light. An angular distribution of the exposure light is thus determined. A two-dimensional charge-coupled device (CCD) sensor or a line sensor can be used as the detector 16.

As illustrated in FIG. 14B, a similar measurement can be performed by providing the mask 13 including a pinhole on the object plane side of the projection optical system.

As described above, measurement data on an effective light source and data concerning a parameter of a component in the illumination optical system can be included in the database for searching for an exposure condition. For example, a database including measurement data of an effective light source can be used in step S112 of the second exemplary embodiment.

According to the present exemplary embodiment, since data of the actually measured effective light source can be used, an exposure condition considering differences between exposure apparatuses that are designed and manufactured under the same specifications can be searched for.

### Fifth Exemplary Embodiment

A fifth exemplary embodiment of the present invention will now be described. According to the present exemplary embodiment, a light blocking member or a light attenuation member is used in the illumination optical system. Descriptions of components that are the same as or alternatively similar to ones in the above-described first exemplary embodiment are omitted for simplification. Descriptions on components similar to those in the above-described exemplary embodiments are omitted for simplification.

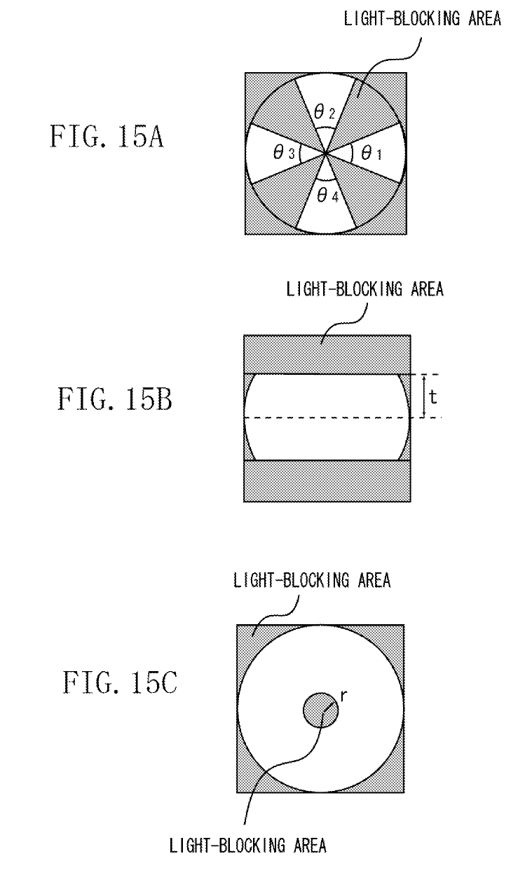

According to the effective light source using a zoom optical system described in the first exemplary embodiment, if the illumination is a quadrupole illumination as illustrated in FIG. 6A, a solution may not be found even if the prism or the zoom optical system is utilized to the maximum extent. In such a case, a light blocking member illustrated in FIG. 15A is arranged on the pupil plane of the illumination optical system or the first light distribution plane to limit aperture angles θ1, θ2, θ3, and θ4. The aperture angle is one of constraint conditions of the light blocking member. However, if the aperture angle is small, then an issue of limit in manufacturing the light blocking member rises. Thus, the range of the aperture angle of the light blocking member is limited and the aperture angle is used as a parameter.

Further, a light blocking member having a light blocking area such as the one illustrated in FIG. 15B can be arranged between the diffractive optical element 3 and the first light distribution plane to partially block the light. In this case, a length “t” in FIG. 15B can be used as a parameter.

If the illumination is annular, a circular light blocking member illustrated in FIG. 15C can be arranged on the first light distribution plane or the pupil plane of the illumination optical system to increase a setting range of the annular ratio. In this case, a radius “r” of the circle can be used as a parameter.

In this way, an appropriate exposure condition can be calculated using the shape of the light blocking member as a constraint condition or a parameter.

On the other hand, a neutral density (ND) filter can be arranged on the pupil plane of the illumination optical system as a light attenuation member. By using the light attenuation member, a light intensity can be changed without changing the outer shape of the effective light source. One ND filter can be used for changing the light intensity. However, two or more rotationally asymmetrical neutral density filters can also be used.

If the light blocking member or the light attenuation member is used, the use efficiency of a quantity of light emitted from the light source (ratio of the quantity of light output from the light source to the quantity of light on the wafer) may decrease. However, by adding this use efficiency to the constraint condition, light quantity loss according to the optical element in the illumination optical system can be minimized. As a realistic value, the light quantity loss is, for example, 50% or lower.

According to the present exemplary embodiment, by using a light blocking member or a light attenuation member, a search range of solution of the effective light source that can be actually formed by the exposure apparatus can be increased, and an exposure condition that can realize higher resolution can be calculated.

### Sixth Exemplary Embodiment

A sixth exemplary embodiment of the present invention will now be described. In the following description, a detailed description will be omitted for the components that are the same as or alternatively similar to those in the above-described exemplary embodiments. According to the present exemplary embodiment, the first light distribution is directly deformed. Since data on optical elements required to form the first light distribution can be determined relatively easily, a calculation time can further be shortened.

First, when a light intensity exists only in an area γ with coordinates (x1, y1) on the first light distribution plane, the effective light source is calculated for each parameter a, b, c, . . . , including a combination of optical elements included in the effective light source forming unit.

γ′(x1, y1)=γ(x1, y1)×f′(x1, y1, a, b, c, . . . ) (3)

effective light source distribution=ΣΣγ′(x1, y1) (4)

γ(x1, y1) in equation (3) represents a light intensity at the coordinates (x1, y1) on the first light distribution plane. Further, f′ (x1, y1, a, b, c, . . . ) represents a light intensity on the pupil plane when the light intensity exists only at the coordinates (x1, y1) on the first light distribution plane. Light intensity per unit area on the first light distribution plane in this case is to be the same as the light intensity in the whole area γ.

A relationship between γ (x1, y1) and γ′ (x1, y1) can be obtained from a mathematical expression regarding intensity having an exposure parameter as a variable, stored as a simulation calculation result file, or obtained from a measurement result using the exposure apparatus. γ′ (x1, y1) expresses a light intensity on the pupil plane if the light intensity exists only at the coordinates (x1, y1) on the first light distribution plane and if the exposure parameter is a, b, c, . . . . This light intensity involves the light intensity at coordinates (x1, y1) on the first light distribution plane according to equation (3). By calculating the entire first light distribution plane using this result according to equation (4), an effective light source corresponding to the first light distribution can be obtained.

However, considering durability of lens material, the upper limit of the light intensity at any portion of the first light distribution can be limited to be below a certain value.

This technique is effective not only in forming an annular illumination having a small annular ratio but also in changing a portion of the annular illumination where the sectional light intensity is highest. Further, it is useful in searching for an effective light source having a shape other than the above-described off-axis illuminations. Further, by calculating an exposure condition as described in the aforementioned exemplary embodiments, a combination of appropriate optical elements and a parameter of the components can be calculated using the exposure condition. Accordingly, a time required for calculation can be shortened since the obtained result can set as an initial value.

Further, since a relationship between the light emitting area γ on the first light distribution plane and the light-receiving distribution γ′ on the pupil plane is known, the effective light source can be calculated if the first light distribution is acquired. Thus, the above-described exemplary embodiments can be applied by calculating the effective light source that can be actually formed by the exposure apparatus using a mathematical expression or database on a simulation calculation result file. In this case, the following steps (1) through (4) are performed each time a parameter of the component constituting the illumination optical system is changed:

(1) Read the light intensity in the area γ on the first light distribution plane.

(2) Calculate the light intensity γ′ on the pupil plane when light is emitted from the area γ.

(3) Store the result obtained in step (2).

(4) Repeat steps (1) through (3) on a different area having a light intensity on the first light distribution plane. In this way, the effective light source is calculated and the image performance of the pattern is evaluated.

Furthermore, an effective light source corresponding to the parameter of the component constituting the illumination optical system can be calculated in advance from the relationship between the light emitting area γ and the light-receiving distribution γ′. In this case, since the effective light source can be directly calculated from the parameter, a time required to calculate the effective light source can be shortened.

### Seventh Exemplary Embodiment

Next, a method for manufacturing a device, such as a semiconductor IC device or a liquid crystal display element, under the exposure condition calculated according to the above-described exemplary embodiments will be described. Under the exposure condition that is calculated as described above according to the above-described exemplary embodiments, an original plate is illuminated and an image of a pattern is projected onto a substrate, such as a wafer or a glass substrate, which is coated with a photosensitive material through a projection optical system. Then, the device is manufactured through processes, such as developing the substrate (photosensitive material), and other known processes including etching, resist stripping, dicing, bonding, and packaging, using the above-described exposure apparatus. According to the device manufacturing method, a device with improved quality can be manufactured.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Application No. 2007-239308 filed Sep. 14, 2007, which is hereby incorporated by reference herein in its entirety.

What is claimed is:

1. A computer-readable storage medium for causing a computer to execute determination of an exposure condition for use in illuminating an original plate with an illumination optical system and projecting an image of a pattern of the original plate onto a substrate through a projection optical system, the program causing the computer to perform operations comprising:
setting a light intensity distribution on a pupil plane in the illumination optical system based on a constraint condition concerning an optical element constituting the illumination optical system;
calculating the image of the pattern of the original plate to be projected onto the substrate using the light intensity distribution; and
determining the exposure condition for exposing the substrate with the image of the pattern of the original plate based on a calculation result of the image of the pattern of the original plate and the constraint condition.

2. The computer-readable storage medium according to claim 1, wherein the constraint condition includes at least one of a movable range of a zoom lens in the illumination optical system, an angle range of ridge lines of a prism in the illumination optical system, a shape of a light blocking member in the illumination optical system, energy density of light incident on the optical element in the illumination optical system, and illuminance on the substrate.

3. A computer-readable storage medium storing a program for causing a computer to execute determination of an exposure condition for use in illuminating an original plate using an illumination optical system and projecting an image of a pattern of the original plate onto a substrate through a projection optical system, the program causing the computer to perform operations comprising:
setting a light intensity distribution by selecting data from a data group of light intensity distributions formable by the illumination optical system on a pupil plane in the illumination optical system;
calculating the image of the pattern of the original plate to be projected onto the substrate using the light intensity distribution; and
determining an exposure condition for exposing the substrate with the image of the pattern of the original plate based on a calculation result of the image of the pattern of the original plate and the data group.

4. The computer-readable storage medium according to claim 3, wherein each item of data stored in the data group includes data obtained by measuring the light intensity distribution on the pupil plane in the illumination optical system or precalculated data.

5. The computer-readable storage medium according to claim 1, wherein the operations further comprise evaluating the calculation result of the image of the pattern of the original plate, and
wherein an index for evaluating the calculation result includes at least one of depth of focus, exposure latitude, side-lobe of an intensity distribution of the image, and a critical dimension of the image.

6. The computer-readable storage medium according to claim 3, wherein the operations further include evaluating the calculation result of the image of the pattern of the original plate, and
wherein an index for evaluating the calculation result includes at least one of depth of focus, exposure latitude, side-lobe of an intensity distribution of the image, and a critical dimension of the image.

7. The computer-readable storage medium according to claim 5, wherein the operations further include determining the exposure condition such that at least one of depth of focus, exposure latitude, and gradient of the intensity distribution of the image becomes maximal.

8. The computer-readable storage medium according to claim 6, wherein the operations further include determining the exposure condition such that at least one of depth of focus, exposure latitude, and gradient of the intensity distribution of the image becomes maximal.

9. The computer-readable storage medium according to claim 1, wherein the exposure condition includes a polarization state of light on the pupil plane in the projection optical system.

10. The computer-readable storage medium according to claim 3, wherein the exposure condition includes a polarization state of light on the pupil plane in the projection optical system.

11. A method for determining, using a computer, an exposure condition for use in illuminating an original plate with an illumination optical system and projecting an image of a pattern of the original plate onto a substrate through a projection optical system, the method comprising:
setting a light intensity distribution on a pupil plane in the illumination optical system based on a constraint condition concerning an optical element constituting the illumination optical system;
calculating the image of the pattern of the original plate to be projected onto the substrate using the light intensity distribution; and
determining an exposure condition for exposing the substrate with the image of the pattern of the original plate based on a calculation result of the image of the pattern of the original plate and the constraint condition.

12. An exposure method for illuminating an original plate with an illumination optical system and projecting an image of a pattern of the original plate onto a substrate through a projection optical system, the exposure method comprising exposing the substrate with the image of the pattern of the original plate using an exposure condition determined using the method according to claim 11.

13. A device manufacturing method comprising:
exposing a substrate with an image of a pattern of an original plate using the exposure method according to claim 12;
developing the exposed substrate; and
forming a device using the developed substrate.

14. A method for determining, using a computer, an exposure condition for use in illuminating an original plate with an illumination optical system and projecting an image of a pattern of the original plate onto a substrate through a projection optical system, the method comprising:
setting a light intensity distribution by selecting data from a data group of light intensity distributions formable by the illumination optical system on a pupil plane in the illumination optical system;
calculating image of the pattern of the original plate to be projected onto the substrate using the light intensity distribution; and
determining the exposure condition for exposing the substrate with the image of the pattern of the original plate based on a calculation result of the image of the pattern of the original plate and the data group.

15. An exposure method for illuminating an original plate with an illumination optical system and projecting an image of a pattern of the original plate onto a substrate through a projection optical system, the exposure method comprising exposing the substrate with the image of the pattern of the original plate using an exposure condition determined using the method according to claim 14.

16. A device manufacturing method comprising:
exposing a substrate with an image of a pattern of an original plate using the exposure method according to claim 15;
developing the exposed substrate; and
forming a device using the developed substrate.
